(19) United States
(12) Patent Application Publication
(10) Pub. No.: US 2008/0295884 A1
(43) Pub. Date: Dec. 4, 2008

(54) Method of making a photovoltaic device or front substrate with barrier layer for use in same and resulting product

(76) Inventors: Pramod K. Sharma, Ann Arbor, MI (US); Thomas J. Taylor, Oakland, NJ (US)

Correspondence Address: NIXON & VANDERHYE, PC, 901 NORTH GLEBE ROAD, 11TH FLOOR, ARLINGTON, VA, 22203, US

(21) Appl. No.: 11/806,065

(22) Filed: May 29, 2007

(51) Int. Cl. H01L 31/04; B05D 5/00; B32B 15/00

(52) U.S. Cl. 136/256; 427/74; 428/615

(57) ABSTRACT

A method of making a photovoltaic device including an antireflective coating, including: forming a coating solution by mixing a mono-metal oxide, a bi-metal oxide, a silane, or a siloxane with a solvent, such that the coating solution may be used as a barrier between the antireflective coating and a glass substrate that inhibits sodium ion migration in the glass substrate after exposure to environmental factors including humidity and temperature. A photovoltaic device including a photovoltaic film, a glass substrate, and a barrier layer provided on the glass substrate; an anti-reflection coating provided on the glass substrate and on the barrier layer; wherein the barrier layer comprises one or more of the following: a mono-metal oxide, a bi-metal oxide, a silane, or a siloxane.

Certain example embodiments of this invention relate to a method of making an antireflective (AR) coating supported by a barrier layer and a substrate (e.g., glass substrate) for use in a photovoltaic device or the like. The barrier layer includes, in certain exemplary embodiments, mono-metal oxide(s), bi-metal oxide(s), silane(s), and/or siloxane(s). The barrier layer may, for example, be deposited on glass used as a superstrate for the production of photovoltaic devices, although it also may used in other applications. While certain example embodiments of this invention relate to a method of making such a coated article or photovoltaic device, other example embodiments relate to the product(s).

### BACKGROUND AND SUMMARY OF EXAMPLE EMBODIMENTS OF THE INVENTION

UV blocking coatings, anti-reflection (AR) coatings, and photovoltaic cells are known in the art. For example, see U.S. Patent Application Publication No. 2007/0074757, the disclosure of which is hereby incorporated by reference.

Glass is desirable for numerous properties and applications, including optical clarity and overall visual appearance. For some example applications, certain optical properties (e.g., light transmission, reflection and/or absorption) are desired to be optimized. For example, in certain example instances, reduction of light reflection from the surface of a glass substrate may be desirable for storefront windows, display cases, photovoltaic devices such as solar cells, picture frames, other types of windows, and so forth.

Photovoltaic devices such as solar cells (and modules therefor) are known in the art. Glass is an integral part of most common commercial photovoltaic modules, including both crystalline and thin film types. A solar cell/module may include, for example, a photoelectric transfer film made up of one or more layers located between a pair of substrates. One or more of the substrates may be of glass, and the photoelectric transfer film (typically semiconductor) is for converting solar energy to electricity. Example solar cells are disclosed in U.S. Pat. Nos. 4,510,344, 4,806,436, 6,506,622, 5,977,477, and JP 07-122764, the disclosures of which are hereby incorporated herein by reference.

Substrate(s) in a solar cell/module are sometimes made of glass. Incoming radiation passes through the incident glass substrate of the solar cell before reaching the active layer(s) (e.g., photoelectric transfer film such as a semiconductor) of the solar cell. Radiation that is reflected by the incident glass substrate does not make its way into the active layer(s) of the solar cell, thereby resulting in a less efficient solar cell. In other words, it would be desirable to decrease the amount of radiation that is reflected by the incident substrate, thereby increasing the amount of radiation that makes its way to the active layer(s) of the solar cell. In particular, the power output of a solar cell or photovoltaic (PV) module may be dependant upon the amount of light, or number of photons, within a specific range of the solar spectrum that pass through the incident glass substrate and reach the photovoltaic semiconductor.

Because the power output of the module may depend upon the amount of light within the solar spectrum that passes through the glass and reaches the PV semiconductor, certain attempts have been made in an attempt to boost overall solar transmission through glass used in PV modules. One attempt is the use of iron-free or “clear” glass, which may increase the amount of solar light transmission when compared to regular float glass, through absorption minimization.

In some circumstances, the sodium ions are present in glass, and the ions may migrate to the surface, possibly due to high humidity and/or high temperature. This migration may cause a reduction in the transmission of light and/or radiation through the AR coating, hence affecting the photovoltaic module's performance. Thus, there may be a need to minimize the sodium ion migration from the bulk of the glass to the surface. Inhibiting sodium ion migration may minimize the reduction in transmission of AR coatings under high humidity conditions and may form an more environmentally durable AR coatings. Furthermore, the power of a PV module can be improved in certain example embodiments of this invention.

The concentration of the sodium oxide(s) within the substrate may vary depending on the particular type of glass. After the substrate cools, for example, there are generally sodium ions remaining in the silicate matrix of the glass. If the glass substrate is exposed to high humidity and/or temperature, these sodium ions may start to migrate from the bulk of the glass to the surface of the substrate. If there is a coating (e.g., an AR coating) on top of the glass, these ions may degrade the coatings in a number of different ways. For example, sometimes the ions react with the coatings, causing them to get wiped off. In other cases, the ions may cause a whitish cloudiness in presence of silica. This cloudiness may, for example, comprise a white sodium silicate.

Furthermore, the affects of sodium oxide(s)-induced corrosion may depend on the temperature and/or humidity of the environment. In some circumstances, the degradation of the glass substrate may cause pitting in the glass and/or lead to a irregular glass surface. If the glass degrades over time (e.g., though exposure to potentially harmful environmental factors, such as high temperature and/or humidity), the transmission of light or other radiation through the glass—either alone or coated—may decrease. While it is believed that the migration of the sodium ions (e.g., to the surface of the glass substrate) cannot necessarily be totally and completely prevented, it can be minimized or diminished in accordance with at least one aspect of the present disclosure.

Thus there may exist a need for a barrier layer that can be used in conjunction with a substrate (e.g., a glass substrate), which prevents or minimizes a decrease in transmissivity over time when exposed to environmental conditions (such as high temperature and/or high humidity).

Thus, it will be appreciated that there may exist a need for an improved AR coating with a barrier coating, for solar cells or other applications, to reduce reflection off glass and other substrates.

### BRIEF SUMMARY OF EXAMPLE EMBODIMENTS OF THE INVENTION

Certain example embodiments of this invention relate, in part, to the formulation and manufacture of barrier layers, which include mono-metal oxide, a bi-metal oxide, a silane, and/or a siloxane, for use in connection with glass intended to be used as a substrate in a photovoltaic device or the like. These barrier layer(s) may inhibit sodium ion migration in the glass, thereby improving the efficiency and/or power of the photovoltaic device in certain example embodiments.

In certain example embodiments of this invention, the present invention relates to a method of making a photovoltaic device including an antireflective coating, the method comprising: forming a coating solution by mixing a mono-metal oxide, a bi-metal oxide, a silane, or a siloxane with a solvent, such that the coating solution may be used as a barrier between the antireflective coating and a glass substrate that inhibits sodium ion migration in the glass substrate after exposure to environmental factors including humidity and temperature; casting the coating solution to form a barrier layer on a glass substrate; curing and/or heat treating the layer, and using the resulting barrier layer as at least part of an antireflective film on the glass substrate in a photovoltaic device; and forming the antireflective layer on the barrier layer, wherein the antireflective layer is on a light incident side of the glass substrate.

In certain example embodiments of this invention, there is provided a method of making a environmentally durable coating for a substrate, the method comprising: forming a coating solution by mixing a mono-metal oxide, a bi-metal oxide, a silane, or a siloxane with a solvent, such that the coating solution may be used as a barrier that inhibits loss of transmission of radiation through the substrate after exposure to environmental factors including humidity and temperature; casting the coating solution to form a barrier layer on the substrate; and curing and/or heat treating the layer.

The barrier layer(s) are advantageous, for example, in that they may inhibit the degradation of the substrate over time when exposed to certain environmental factors, such as high temperature and humidity.

In certain exemplary embodiments, there is provided a coated article comprising: a glass substrate; a barrier layer provided on the glass substrate; and an anti-reflection coating provided on the barrier layer; wherein the barrier layer comprises one or more of the following: a mono-metal oxide, a bi-metal oxide, a silane, or a siloxane.

In certain exemplary embodiments, there is provided a photovoltaic film, and at least a glass substrate on a light incident side of the photovoltaic film; a barrier layer provided on the glass substrate; an anti-reflection coating provided on the glass substrate and on the barrier layer; wherein the barrier layer comprises one or more of the following: a mono-metal oxide, a bi-metal oxide, a silane, or a siloxane.

In certain exemplary embodiments, the glass substrate comprises a soda-lime-silica glass including the following ingredients: SiO₂, 67-75% by weight; Na₂O, 10-20% by weight; CaO, 5-15% by weight; MgO, 0-7% by weight; Al₂O₃, 0-5% by weight; K₂O, 0-5% by weight; Li₂O, 0-1.5% by weight; and BaO, 0-1%, by weight.

In certain exemplary embodiments, the mono-metal oxide is selected from the group consisting of alumina, magnesia, titania, ZnO, CaO, Y₂O₃, ZrO₂, MnO, and NiO.

In certain exemplary embodiments, the bi-metal oxide is selected from two mono-metal oxides from the group consisting of alumina, magnesia, titania, ZnO, CaO, Y₂O₃, ZrO₂, MnO, and NiO.

In certain exemplary embodiments, the silane is selected from the group consisting of tetra ethoxy silane, methyltrimethoxysilane, methyltriethoxysilane, ethyltrimethoxilane, propyltrimethoxysilane, isobutyltrimethoxysilane, octatryethoxysilane, phenyltriethoxysilane, tetramethoxysilane, acetoxyproplytrimethoxysilane, 3 aminopropyltrimethoxysilane, 3 cyanopropyltriethoxysilane, and 3 glycidoxypropyl trimethoxisilane.

In certain exemplary embodiments, the siloxane is selected from the group consisting of hexaethylcyclotrisiloxane, hexaethyl disiloxane, 1,1,3,3,5,5-hexamethyltrisiloxane, hexamethylcyclotrisiloxane, hexavinyldisiloxane, hexaphenyldisiloxane, octaphenylcyclotetrasiloxane, hexachlorodisiloxane, dichlorooctamethyltetrasiloxane, 2-methoxy(polyethyleneoxy)propyl)heptamethyl trisiloxane, 3 acryloxypropyl tris trimethyl siloxysilane, methylacryloxypropyl heptacyclopentyl-T8silsesquioxane, octakis(dimethylsiloxy)octaprismosilsesquioxane, and octaviny-T8-silsesquioxane.

### BRIEF DESCRIPTION OF THE DRAWINGS

FIG. 1 is a cross-sectional view of a coated article including a barrier layer made in accordance with an example embodiment of this invention (this coated article of FIG. 1 may be used in connection with a photovoltaic device or in any other suitable application in different embodiments of this invention).

FIG. 2 is a cross-sectional view of a photovoltaic device that may use the coated article of FIG. 1.

### DETAILED DESCRIPTION OF EXAMPLE EMBODIMENTS OF THE INVENTION

Referring now more particularly to the accompanying drawings in which like reference numerals indicate like parts throughout the several views.

This invention relates to barrier layers provided for coated articles that may be used in devices such as photovoltaic devices, storefront windows, display cases, picture frames, other types of windows, and the like. In certain example embodiments (e.g., in photovoltaic devices), the barrier layer may be provided between on either the light incident side or the other side of the substrate (e.g., glass substrate).

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, single or tandem thin-film solar cells, CdS and/or CdTe photovoltaic devices, polysilicon and/or microcrystalline Si photovoltaic devices, and the like.

In certain example embodiments of this invention, an improved coating system comprising a barrier layer is provided on an incident glass substrate of a photovoltaic device such as a solar cell or the like. This coating system may function to reduce reflection of light from the glass substrate, thereby allowing more light within the solar spectrum to pass through the incident glass substrate and reach the photovoltaic semiconductor film so that the device can be more efficient. In other example embodiments of this invention, such a coating system is used in applications other than photovoltaic devices, such as in storefront windows, display cases, picture frames, other types of windows, and the like. The glass substrate may be a glass superstrate or any other type of glass substrate in different instances.

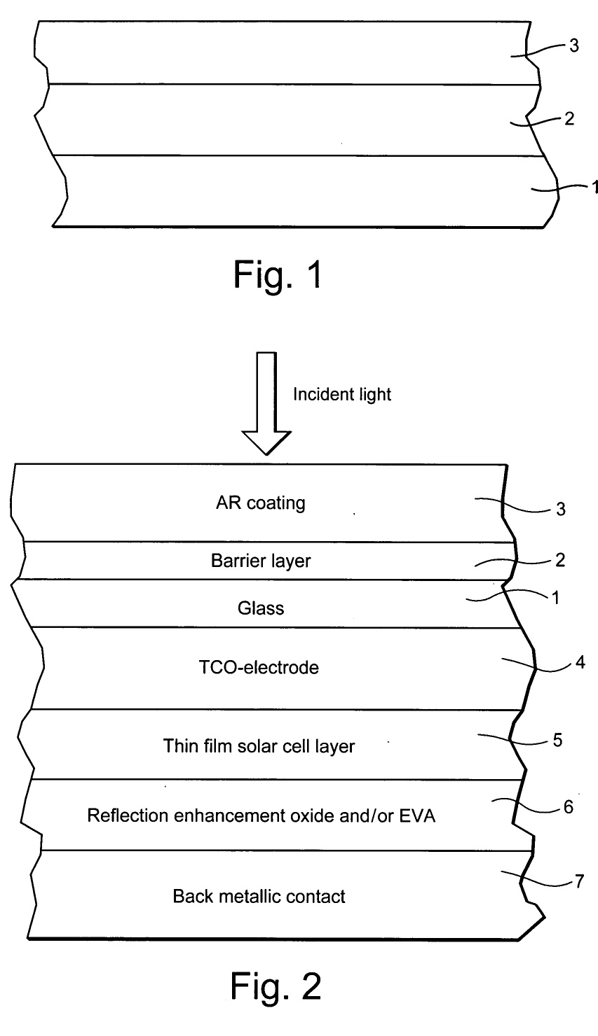

FIG. 1 is a cross sectional view of a coated article according to an example embodiment of this invention. The coated article of FIG. 1 includes a glass substrate 1, an AR coating 3, and a barrier layer 2 disposed between substrate 1 and AR coating 3. In certain exemplary embodiments, the AR coating 3 is optional. Furthermore, it is also possible to form other layer(s) between barrier layer 2 and AR coating 3, and/or between glass substrate 1 and barrier layer 2, in different example embodiments of this invention.

In the FIG. 1 embodiment, the antireflective coating 3 includes a suitable antireflective composition, such as, for example, porous silica, which may be produced using the sol-gel process. The antireflective composition may contain at least one adjuvant to increase the hardness, durability, transmissivity, and/or other properties of the coating 3, although the precise composition of the porous silica is unimportant. The coating 3 may be any suitable thickness in certain example embodiments of this invention.

Optionally, the AR coating 3 may also include an overcoat of or including material such as silicon oxide (e.g., SiO₂), or the like, which may be provided over the first layer 3 in certain example embodiments of this invention as shown in FIG. 1. The overcoat layer may be deposited over layer 3 in any suitable manner. For example, a Si or SiAl target could be sputtered in an oxygen and argon atmosphere to sputter-deposit the silicon oxide inclusive layer. Alternatively, the silicon oxide inclusive layer could be deposited by flame pyrolysis, or any other suitable technique such as spraying, roll coating, printing, via silica precursor sol-gel solution (then drying and curing), coating with a silica dispersion of nano or colloidal particles, vapor phase deposition, and so forth. It is noted that it is possible to form other layer(s) over an overcoat layer in certain example instances. It is noted that layer 3 may be doped with other materials such as titanium, aluminum, nitrogen or the like.

In certain example embodiments of this invention, high transmission low-iron glass may be used for glass substrate 1 in order to further increase the transmission of radiation (e.g., photons) to the active layer(s) of the solar cell or the like. For example and without limitation, the glass substrate 1 may be of any of the glasses described in any of U.S. patent application Ser. Nos. 11/049,292 and/or 11/122,218, the disclosures of which are hereby incorporated herein by reference. Furthermore, additional suitable glasses include, for example (i.e., and without limitation): standard clear glass; and/or low-iron glass, such as Guardian's ExtraClear, UltraWhite, or Solar. No matter the composition of the glass substrate, certain embodiments of anti-reflective coatings produced in accordance with the present invention may increase transmission of light to the active semiconductor film 5 (one or more layers) of the photovoltaic device and/or have a desirable or improved resistivity to scratching.

Certain glasses for glass substrate 1 (which or may not be patterned in different instances) according to example embodiments of this invention utilize soda-lime-silica flat glass as their base composition/glass. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients: SiO₂, 67-75% by weight; Na₂O, 1-20% by weight; CaO, 5-15% by weight; MgO, 0-7% by weight; Al₂O₃, O-5% by weight; K₂O, 0-5% by weight; Li₂O, 0-1.5% by weight; and BaO, 0-1%, by weight.

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO, by weight.

In addition to the base glass above, in making glass according to certain example embodiments of the instant invention the glass batch includes materials (including colorants and/or oxidizers) which cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., cerium, erbium and/or the like). In certain example embodiments of this invention, the resulting glass has visible transmission of at least 75%, more preferably at least 80%, even more preferably of at least 85%, and most preferably of at least about 90% (Lt D65). In certain example non-limiting instances, such high transmissions may be achieved at a reference glass thickness of about 3 to 4 mm In certain embodiments of this invention, in addition to the base glass, the glass and/or glass batch comprises or consists essentially of materials as set forth in Table 1 below (in terms of weight percentage of the total glass composition):

TABLE 1
Example Additional Materials In Glass

| Ingredient | General (Wt. %) | More Preferred | Most Preferred |
|---|---|---|---|
| total iron (expressed | 0.001-0.06% | 0.005-0.04% | 0.01-0.03% |
| as Fe₂O₃): | | | |
| cerium oxide: | 0-0.30% | 0.01-0.12% | 0.01-0.07% |
| TiO₂ | 0-1.0% | 0.005-0.1% | 0.01-0.04% |
| Erbium oxide: | 0.05 to 0.5% | 0.1 to 0.5% | 0.1 to 0.35% |

In certain example embodiments, the total iron content of the glass is more preferably from 0.01 to 0.06%, more preferably from 0.01 to 0.04%, and most preferably from 0.01 to 0.03%. In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material. It is noted that while the presence of cerium oxide is preferred in many embodiments of this invention, it is not required in all embodiments and indeed is intentionally omitted in many instances. However, in certain example embodiments of this invention, small amounts of erbium oxide may be added to the glass in the colorant portion (e.g., from about 0.1 to 0.5% erbium oxide).

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

It is noted that the light-incident surface of the glass substrate 1 may be flat or patterned in different example embodiments of this invention.

FIG. 2 is a cross-sectional view of a photovoltaic device (e.g., solar cell), for converting light to electricity, according to an example embodiment of this invention. The solar cell of FIG. 2 uses the AR coating 3 and glass substrate 1 shown in FIG. 1 in certain example embodiments of this invention. In this example embodiment, the incoming or incident light from the sun or the like is first incident on optional AR coating 3, passes therethrough and then through barrier layer 2 and through glass substrate 1 and front transparent conductive electrode 4 before reaching the photovoltaic semiconductor (active film) 5 of the solar cell. Note that the solar cell may also include, but does not require, a reflection enhancement oxide and/or EVA film 6, and/or a back metallic or otherwise conductive contact and/or reflector 7 as shown in example FIG. 2. Other types of photovoltaic devices may of course be used, and the FIG. 2 device is merely provided for purposes of example and understanding. As explained above, the barrier layer 2 may reduce reflections and/or absorptions of the incident light and permits more light to reach the thin film semiconductor film 5 of the photovoltaic device thereby permitting the device to act more efficiently.

While certain of the coatings discussed above are used in the context of the photovoltaic devices/modules, this invention is not so limited. Coatings and systems according to this invention may be used in other applications such as for picture frames, fireplace doors, and the like. Also, other layer(s) may be provided on the glass substrate under the barrier layer so that the barrier layer is considered on the glass substrate even if other layers are provided therebetween. Similarly, other layer(s) may be provided on the barrier layer 2 under the AR coating 3. Also, while the AR coating 3 is directly on and contacting the barrier layer 2 in the FIG. 1 embodiment, it is possible to provide other layer(s) between the barrier layer and AR coating in alternative embodiments of this invention.

Set forth below is a description of how barrier layer 2 may be made according to certain example non-limiting embodiments of this invention.

Exemplary embodiments of this invention provide a method of making a coating solution containing mono-metal oxide(s), bi-metal oxide(s), silane(s), and/or siloxane(s) for use as the barrier layer 2. In certain example embodiments of this invention, the coating solution may be based on a mixture of at least a mono-metal oxide and/or a bi-metal oxide, optionally a carboxylate (such as acetylacetate), optionally an acid (such as hydrochloric acid), and a solvent. In certain example embodiments of this invention, the coating solution may be based on a mixture of at least a silica sol and a silane and/or siloxane. The silica sol may, for example, be based on two different silica precursors, namely (a) a colloidal silica solution including or consisting essentially of particulate silica in a solvent and (b) a polymeric solution including or consisting essentially of silica chains.

In making the polymeric silica solution for the silica sol, a silane may be mixed with a catalyst, solvent and water. After agitating, the colloidal silica solution (a) is added to the polymeric silica solution (b), optionally with a solvent. After and/or before agitating the silica sol, it is mixed, combined, and/or agitated with the mono-metal oxide(s), bi-metal oxide(s), silane(s), and/or siloxane(s).

The coating solution is then deposited on a suitable substrate such as a highly transmissive clear glass substrate, directly or indirectly. Then, the coating solution on the glass 1 substrate is cured and/or fired, preferably from about 100 to 750° C., and all subranges therebetween, thereby forming the solid barrier layer 2 on the glass substrate 1. The final thickness of the barrier layer 3 may, though not necessarily, be approximately a quarter wave thickness in certain example embodiments of this invention. In certain example embodiments, the AR coating may have a thickness ranging from 10 to 200 nm, preferably from 50 to 110, and even more preferably from 175 to 185 nm. It has been found that an AR coating made in such a manner may have adequate longevity, thereby overcoming one or more of the aforesaid environmentally induced durability problems in approaches of the prior art.

In an exemplary embodiment, the sol-gel process used in forming barrier layer 2 may comprise: forming a polymeric component of silica by mixing glycycloxypropyltrimethoxysilane (which is sometimes referred to as “glymo”) with a first solvent, a catalyst, and water; forming a silica sol gel by mixing the polymeric component with a colloidal silica and a second solvent; mixing the silica sol with mono-metal oxide(s), bi-metal oxide(s), silane(s), and/or siloxane(s); casting the mixture by spin coating to form a coating on the glass substrate; and curing and heat treating the coating. Suitable solvents may include, for example, n-propanol, isopropanol, other well-known alcohols (e.g., ethanol), and other well-known organic solvents (e.g., toluene). Suitable catalysts may include, for example, well-known acids, such as hydrochloric acid, sulfuric acid, acetic acid, nitric acid, etc. The colloidal silica may comprise, for example, silica and methyl ethyl ketone. The mixing of the silica sol and siloxane may occur at or near room temperature for 15 to 45 minutes (and preferably around 30 minutes) or any other period sufficient to mix the two sols either homogeneously or nonhomogeneously. The curing may occur at a temperature between 100 and 150° C. for up to 2 minutes, and the heat treating may occur at a temperature between 600 and 750° C. for up to 5 minutes. Shorter and longer times with higher and lower temperatures are contemplated within exemplary embodiments of the present invention.

In certain exemplary embodiments, the coating solution contains at least one mono-metal oxides, such as, for example, alumina, magnesia, titania, ZnO, CaO, Y₂O₃, ZrO₂, MnO, NiO, etc. In certain exemplary embodiments, the coating solution contains at least one bi-metal oxide, for example, by combining any two or more mono-metal oxide (including those identified above). In some exemplary embodiments, for example, the bi-metal oxide comprises x % Al₂0₃ and y % MgO, where x+y≦100. In certain exemplary embodiments, the coating solution contains at least one silane, such as, for example, TEOS, methyltrimethoxysilane, methyltriethoxysilane, ethyltrimethoxilane, propyltrimethoxysilane, isobutyltrimethoxysilane, octatryethoxysilane, phenyltriethoxysilane, tetramethoxysilane, acetoxyproplytrimethoxysilane, 3 aminopropyltrimethoxysilane, 3 cyanopropyltriethoxysilane, 3 glycidoxypropyl trimethoxisilane, etc. In certain exemplary embodiments, the coating solution contains at least one siloxane, such as, for example, an alkyl type (such as, for example, hexaethylcyclotrisiloxane, hexaethyl disiloxane, 1,1,3,3,5,5-hexamethyltrisiloxane, hexamethylcyclotrisiloxane, hexavinyldisiloxane, hexaphenyldisiloxane, octaphenylcyclotetrasiloxane, etc.), a chloro type (such as, for example, hexachlorodisiloxane, dichlorooctamethyltetrasiloxane, etc.), a acryloxy type (such as, for example, 2-methoxy(polyethyleneoxy)propyl)heptamethyl trisiloxane, 3 acryloxypropyl tris trimethyl siloxysilane, etc.), a hydrogen silsesquioxane (such as, for example, methylacryloxypropyl heptacyclopentyl-T8silsesquioxane, octakis(dimethylsiloxy)octaprismosilsesquioxane, octaviny-T8-silsesquioxane, etc.), etc.

In alternative embodiments, two or more mono-metal oxide(s), bi-metal oxide(s), silane(s), and/or siloxane(s) are mixed to form a coating solution. In further embodiments, one or more additional ingredients, such as organic compounds, metal oxide(s), and/or siloxane(s) may be mixed in during the formation of the sol gel, such as described in a co-pending U.S. patent application Ser. Nos. 11/701,541 (filed Feb. 2, 2007), 11/716,034 (filed Mar. 9, 2007), and 11/797,214 (filed each of which is incorporated herein by reference. Alternatively, other components, such as surfactants (including, for example, sodium dodecylsulfate, sodium cholate, sodium deoxycholate (DOC), N-lauroylsarcosine sodium salt, lauryldimethylamine-oxide (LDAO), cetyltrimethylammoniumbromide (CTAB), bis(2-ethylhexyl)sulfosuccinate sodium salt, etc.) may also be present in the coating solution.

The siloxanes were obtained from Gelest, Inc., and the metal oxide precursors were obtained from Aldrich Chemical Co.

The following examples of different embodiments of this invention are provided for purposes of example and understanding only, and are not intended to be limiting unless expressly claimed.

### (COMPARATIVE) EXAMPLE #1

The silica sol was prepared as follows. A polymeric component of silica was prepared by using 64% wt of n-propanol, 24% wt of glycycloxylpropyltrimethoxysilane (glymo), 7% wt of water, and 5% wt of hydrochloric acid. These ingredients were used and mixed for 24 hrs. The coating solution was prepared by using 21% wt of polymeric solution, 7% wt colloidal silica in methyl ethyl ketone supplied by Nissan Chemicals Inc, and 72% wt n-propanol. This was stirred for 2 hrs to give silica sol. The final solution is referred to as the silica sol. The silica coating was fabricated using spin coating method with 1000 rpm for 18 secs. The coating was heat treated in furnace at 625° C. for three and a half minutes. This coating of example #1 does not have any barrier layer.

The environmental durability of the coating was done under following conditions
Ramp—Heat from room temperature (25° C.) to 85° C. (100 C/hr; Bring relative humidity (RH) up to 85%.
Cycle 1—Dwell @ 85° C./85% RH for 1200 minutes.
Ramp—Cool from 85° C. to −40° C. @ 100 C/hr; Bring RH down to 0%.
Cycle 2—Dwell @ −40° C./0% RH for 40 minutes.
Ramp—Heat from −40° C. to 85° C. @ 100 C/hr; Bring the RH up to 85%.
Repeat—Repeat for 10 cycles or 240 hrs.

The transmission measurements were done using PerkinElmer UV-VIS Lambda 900 before and after the environmental testing. Percent transmission (% T) before and after testing is shown in the table 2.

### EXAMPLE #2

In Example #2, a barrier layer was used which is made from alumina (Al₂O₃). 2.52 gm of aluminum tert butoxide was mixed in a solution containing 2 gm acetylacetate, 6 gm of hydrochloric acid and 20 gm of normal propanol. Stir this solution for 15 minutes. Then add 0.5 gm of water. Stir the solution for another 15 minutes. The final solution is refers as Al₂O₃ sol. The barrier layer of almuna was fabricated using spin coating method with 1000 rpm for 18 secs. The coating was heat treated in furnace at 130° C. for one minute. Then the coating was cooled down to room temperature. AR coating of silica was cast on the barrier layer exactly same method mentioned in the example #1. The coatings were also subjected to the environmental testing as illustrated in the Example #1. Transmission was measured before and after the environmental testing and result shows in table 2.

### EXAMPLE #3

In Example #3, a barrier layer was used which is made from zirconia (ZrO₂). 3.8 gm of zirconium butoxide was mixed in a solution containing 2 gm acetylacetate, 6 gm of hydrochloric acid, 2 gm of nitric acid and 20 gm of normal propanol. Stir this solution for 15 minutes. Then add 0.5 gm of water. Stir the solution for another 15 minutes. The final solution is refers as ZrO₂sol. The barrier layer using zirconia and top layer of AR coating are fabricated exactly similar method as mentioned in example #2. The coatings were also subjected to the environmental testing as illustrated in the Example #1. Transmission was measured before and after the environmental testing and result shows in table 2.

### EXAMPLE #4

In Example #4, a barrier layer was used which is made from mullite (3Al₂O₃:2SiO₂). Mullite sol containing 3 parts of alumina and 2 parts of silica was prepared by taking 2.18 gm of aluminum tert butoxide and 0.73 gm of glycycloxylpropyltrimethoxysilane (glymo) in a solution containing 6 gm acetylacetate, 6 gm of hydrochloric acid and 20 gm of normal propanol. Stir this solution for 15 minutes. Then add 0.5 gm of water. Stir the solution for another 15 minutes. The final solution is refers as 3Al₂O₃:2SiO₂ sol. The barrier layer using mullite and top layer of AR coating are fabricated exactly similar method as mentioned in example #2. The coatings were also subjected to the environmental testing as illustrated in the Example #1. Transmission was measured before and after the environmental testing and result shows in table 2.

### EXAMPLE #5

In Example #5, a barrier layer was used which is made from sillimanite (Al₂O₃: SiO₂) sol. Sillimanite sol containing 1 parts of alumina and 1 parts of silica was prepared by taking 2.45 gm of aluminum tert butoxide and 1.15 gm of glycycloxylpropyltrimethoxysilane (glymo) in a solution containing 2 gm acetylacetate, 6 gm of hydrochloric acid and 20 gm of normal propanol. Stir this solution for 15 minutes. Then add 0.5 gm of water. Stir the solution for another 15 minutes. The final solution is refers as Al₂O₃:SiO₂ sol. The barrier layer using sillimanite and top layer of AR coating are fabricated exactly similar method as mentioned in example #2. The coatings were also subjected to the environmental testing as illustrated in the Example #1. Transmission was measured before and after the environmental testing and result shows in table 2.

### EXAMPLE #6

The example #6, the barrier layer is fabricated using tetra ethoxy silane (TEOS) sol. The TEOS sol was prepared using 10 gm of TEOS in 90 gm of normal propanol. The method of fabrication of barrier coating and top AR coating is exactly similar as mentioned in the Example #2. Transmission was measured before and after the environmental testing and result shows in table 3.

### EXAMPLE #7

The example #7 is same as example #6 except the TEOS, 3,5 bis(3-carboxy propyl)tetramethyl disloxane was used as a barrier layer. The method of fabrication of barrier coating and top AR coating is exactly similar as mentioned in the Example #2. Transmission was measured before and after the environmental testing and result shows in table 3.

### EXAMPLE #8

The example #8, is same as example #6 except the TEOS, 4,3,5-bis(chloromethyl)octamethyl tetrasiloxane was used as a barrier layer. The method of fabrication of barrier coating and top AR coating is exactly similar as mentioned in the Example #2. Transmission was measured before and after the environmental testing and result shows in table 3.

### EXAMPLE #9

The example #9, is same as example #6 except the TEOS, acryloxy-siloxane (1,3 bis(3-methlyacryloxy)tetramethyl disiloxane) was used as a barrier layer. The method of fabrication of barrier coating and top AR coating is exactly similar as mentioned in the Example #2. Transmission was measured before and after the environmental testing and result shows in table 3.

### EXAMPLE #10

The example #10, is same as example #6 except the TEOS, decamethyl trisiloxane was used as a barrier layer. The method of fabrication of barrier coating and top AR coating is exactly similar as mentioned in the Example #2. Transmission was measured before and after the environmental testing and result shows in table 3.

TABLE 1
Types of barrier coatings

| | | Type of Oxide, |
|---|---|---|
| Example # | Barrier coating | Silane, or Siloxane |
| (Comparative) | No barrier coating | |
| Example #1 | | |
| Example #2 | Mono-metal oxide | Alumina |
| Example #3 | Mono-metal oxide | Zirconia |
| Example #4 | Bi-metal oxides | Mullite |
| Example #5 | Bi-metal oxides | Sillimanite |
| Example #6 | Silane | Tetraethoxysilane |
| Example #7 | Siloxane | Carbboxy-disiloxane |
| Example #8 | Siloxane | Chloro-tetrasiloxane |
| Example #9 | Siloxane | Acryloxy-disiloxane |
| Example #10 | Siloxane | Methyl-disiloxane |

TABLE 2
Barrier layer based on metal oxides

| | |
|---|---|
| % T | % Reduction |

| Examples | 0-Day | 11-Day | in T |
|---|---|---|---|
| (Comparative) | 90.6 | 76.9 | 13.7 |
| Example #1 | | | |
| Example #2 | 90.2 | 82.5 | 7.7 |
| Example #3 | 90.2 | 81.4 | 8.4 |
| Example #4 | 90.1 | 78.1 | 12 |
| Example #5 | 90.2 | 79 | 11.3 |

TABLE 3
Barrier layer based on silica and siloxanes

| | |
|---|---|
| % T | % Reduction |

| Examples | 0-Day | 11-Day | in T |
|---|---|---|---|
| Example #6 | 90.7 | 79.4 | 11.3 |
| Example #7 | 89.9 | 71.4 | 18.5 |
| Example #8 | 90 | 75.1 | 14.9 |
| Example #9 | 90.2 | 83.1 | 7.1 |
| Examples #10 | 90.1 | 81.7 | 8.4 |

As illustrated in tables 2 and 3, the reduction in % T can be reduced to as low as 7% if the barrier coating is used by alumina underneath a AR coating; the reduction in % T can be reduced to as low as 11% if the barrier coating is used by silica underneath a AR coating; and the reduction in % T can be reduced to as low as 8% if the barrier coating is used by siloxane underneath a AR coating.

All numerical ranges and amounts are approximate and include at least some variation.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a photovoltaic device including an antireflective coating, the method comprising:
forming a coating solution by mixing a mono-metal oxide, a bi-metal oxide, a silane, and/or a siloxane with a solvent, such that the coating solution may be used as a barrier between the antireflective coating and a glass substrate that reduces sodium ion migration from the glass substrate;
providing the coating solution on the glass substrate to form a barrier layer;
curing the barrier layer;
providing an antireflective film on the glass substrate over at least the barrier layer; and
using the coated glass substrate including the cured barrier layer in a photovoltaic device, wherein the barrier layer is located under the antireflective film provided on the glass substrate in the photovoltaic device, and the barrier layer and antireflective film are provided on a light incident side of the glass substrate.

2. The method of claim 1, wherein the curing is performed using at least heat treating and occurs at a temperature between 100 and 150° C. and has a duration of no more than about 2 minutes.

3. The method of claim 1, wherein the solution comprises at least one mono-metal oxide that is selected from the group consisting of alumina, magnesia, titania, ZnO, CaO, Y₂O₃, ZrO₂, MnO, and NiO

4. The method of claim 1, wherein the solution comprises at least one bi-metal oxide that is selected from two mono-metal oxides from the group consisting of alumina, magnesia, titania, ZnO, CaO, Y₂O₃, ZrO₂, MnO, and NiO.

5. The method of claim 1, wherein the solution comprises at least one silane that is selected from the group consisting of tetra ethoxy silane, methyltrimethoxysilane, methyltriethoxysilane, ethyltrimethoxilane, propyltrimethoxysilane, isobutyltrimethoxysilane, octatryethoxysilane, phenyltriethoxysilane, tetramethoxysilane, acetoxyproplytrimethoxysilane, 3 aminopropyltrimethoxysilane, 3 cyanopropyltriethoxysilane, and 3 glycidoxypropyl trimethoxisilane.

6. The method of claim 1, wherein the solution comprises at least one siloxane that is selected from the group consisting of hexaethylcyclotrisiloxane, hexaethyl disiloxane, 1,1,3,3,5,5-hexamethyltrisiloxane, hexamethylcyclotrisiloxane, hexavinyldisiloxane, hexaphenyldisiloxane, octaphenylcyclotetrasiloxane, hexachlorodisiloxane, dichlorooctamethyltetrasiloxane, 2-methoxy(polyethyleneoxy)propyl)heptamethyl trisiloxane, 3 acryloxypropyl tris trimethyl siloxysilane, methylacryloxypropyl heptacyclopentyl-T8silsesquioxane, octakis(dimethylsiloxy)octaprismosilsesquioxane, and octaviny-T8-silsesquioxane.

7. The method of claim 1, wherein the step of forming the coating solution further comprises mixing a carboxylate and an acid with the coating solution.

8. A method of making an environmentally durable coating for a substrate, the method comprising:
forming a coating solution by mixing one or more of a mono-metal oxide, a bi-metal oxide, a silane, and a siloxane with at least one solvent, such that the coating solution is used in forming a barrier layer that reduces loss of transmission of radiation through the substrate after exposure to environmental factors including humidity and temperature;
casting the coating solution to form a barrier layer on the substrate; and
curing the barrier layer using at least heat treatment.

9. A photovoltaic device comprising:
a photovoltaic film, and at least a glass substrate located on a light incident side of the photovoltaic film;
a barrier layer provided on the glass substrate;
an anti-reflection coating provided on the glass substrate over at least the barrier layer;
wherein the barrier layer comprises one or more of: a mono-metal oxide, a bi-metal oxide, a silane, and/or a siloxane.

10. The photovoltaic device of claim 9, wherein the glass substrate comprises a soda-lime-silica glass including the following ingredients: SiO₂, 67-75% by weight; Na₂O, 10-20% by weight; CaO, 5-15% by weight; MgO, 0-7% by weight; Al₂O₃, 0-5% by weight; K₂O, 0-5% by weight; Li₂O, 0-1.5% by weight; and BaO, 0-1%, by weight.

11. The photovoltaic device of claim 10, wherein the mono-metal oxide is selected from the group consisting of alumina, magnesia, titania, ZnO, CaO, Y₂O₃, ZrO₂, MnO, and NiO

12. The photovoltaic device of claim 10, wherein the bi-metal oxide is selected from two mono-metal oxides from the group consisting of alumina, magnesia, titania, ZnO, CaO, Y₂O₃, ZrO₂, MnO, and NiO.

13. The photovoltaic device of claim 10, wherein the silane is selected from the group consisting of tetra ethoxy silane, methyltrimethoxysilane, methyltriethoxysilane, ethyltrimethoxilane, propyltrimethoxysilane, isobutyltrimethoxysilane, octatryethoxysilane, phenyltriethoxysilane, tetramethoxysilane, acetoxyproplytrimethoxysilane, 3 aminopropyltrimethoxysilane, 3 cyanopropyltriethoxysilane, and 3 glycidoxypropyl trimethoxisilane.

14. The photovoltaic device of claim 10, wherein the siloxane is selected from the group consisting of hexaethylcyclotrisiloxane, hexaethyl disiloxane, 1,1,3,3,5,5-hexamethyltrisiloxane, hexamethylcyclotrisiloxane, hexavinyldisiloxane, hexaphenyldisiloxane, octaphenylcyclotetrasiloxane, hexachlorodisiloxane, dichlorooctamethyltetrasiloxane, 2-methoxy(polyethyleneoxy)propyl)heptamethyl trisiloxane, 3 acryloxypropyl tris trimethyl siloxysilane, methylacryloxypropyl heptacyclopentyl-T8silsesquioxane, octakis(dimethylsiloxy)octaprismosilsesquioxane, and octaviny-T8-silsesquioxane.

15. A coated article comprising:
a glass substrate;
a barrier layer provided on the glass substrate;
an anti-reflection coating provided on the barrier layer;
wherein the barrier layer is formed using a solution that comprises one or more of: a mono-metal oxide, a bi-metal oxide, a silane, and/or a siloxane.

16. The coated article of claim 15, wherein the mono-metal oxide is selected from the group consisting of alumina, magnesia, titania, ZnO, CaO, Y₂O₃, ZrO₂, MnO, and NiO

17. The coated article of claim 15, wherein the bi-metal oxide is selected from two mono-metal oxides from the group consisting of alumina, magnesia, titania, ZnO, CaO, Y₂O₃, ZrO₂, MnO, and NiO.

18. The coated article of claim 15, wherein the silane is selected from the group consisting of tetra ethoxy silane, methyltrimethoxysilane, methyltriethoxysilane, ethyltrimethoxilane, propyltrimethoxysilane, isobutyltrimethoxysilane, octatryethoxysilane, phenyltriethoxysilane, tetramethoxysilane, acetoxyproplytrimethoxysilane, 3 aminopropyltrimethoxysilane, 3 cyanopropyltriethoxysilane, and 3 glycidoxypropyl trimethoxisilane.

19. The coated article of claim 15, wherein the siloxane is selected from the group consisting of hexaethylcyclotrisiloxane, hexaethyl disiloxane, 1,1,3,3,5,5-hexamethyltrisiloxane, hexamethylcyclotrisiloxane, hexavinyldisiloxane, hexaphenyldisiloxane, octaphenylcyclotetrasiloxane, hexachlorodisiloxane, dichlorooctamethyltetrasiloxane, 2-methoxy(polyethyleneoxy)propyl)heptamethyl trisiloxane, 3 acryloxypropyl tris trimethyl siloxysilane, methylacryloxypropyl heptacyclopentyl-T8silsesquioxane, octakis(dimethylsiloxy)octaprismosilsesquioxane, and octaviny-T8-silsesquioxane.
